(19) United States
(12) Patent Application Publication
(10) Pub. No.: US 2008/0248611 A1
(43) Pub. Date: Oct. 9, 2008

(54) MANUFACTURING METHOD OF SEMICONDUCTOR DEVICE

(76) Inventors: Kenji HANADA, Tokyo (JP); Norihisa Toma, Tokyo (JP); Masaki Nakanishi, Tokyo (JP); Takahiro Naito, Tokyo (JP); Naotaka Tanaka, Tokyo (JP)

Correspondence Address: MILES & STOCKBRIDGE PC, 1751 PINNACLE DRIVE, SUITE 500, MCLEAN, VA, 22102-3833, US

(21) Appl. No.: 12/037,984

(22) Filed: Feb. 27, 2008

(30) Foreign Application Priority Data
Apr. 9, 2007 (JP) 2007-101493

(51) Int. Cl. H01L 21/60

(52) U.S. Cl. 438/108; 257/E21.519; 257/E21.511

(57) ABSTRACT

The quality and reliability of a semiconductor device can be improved by eliminating a warp of a chip and performing a chip-stack. A wiring substrate, the first semiconductor chip connected via the first gold bump on the wiring substrate, the second semiconductor chip stacked via the second gold bump on the first semiconductor chip, and a sealing body are comprised. A first gold bump is connected to the wiring substrate, heating, and injection by pressure welding of the first gold bump is done under normal temperature after that at the hole-like electrode of the first semiconductor chip. Since injection by pressure welding of the second gold bump of the second semiconductor chip is done under normal temperature into the hole-like electrode of the first semiconductor chip and the second semiconductor chip is stacked, the chip-stack can be performed under normal temperature. The chip after the second stage can be stacked in the state where there is no warp in the first stage chip, by this, and the quality and reliability of the semiconductor device (semiconductor package) can be improved.

### CROSS-REFERENCE TO RELATED APPLICATION

The present application claims priority from Japanese patent application No. 2007-101493 filed on Apr. 9, 2007, the content of which is hereby incorporated by reference into this application.

1. Field of the Invention

The present invention relates to manufacturing technology of a semiconductor device, and particularly relates to an effective technology in the application to the assembly of the semiconductor device which stacks a plurality of semiconductor chips.

2. Description of the Background Art

There is technology which forms a through-hole part in the pad section at the side of a semiconductor element, makes the projection electrode of a substrate side insert in the hole, and connects the substrate with the semiconductor element (for example, refer to Patent Reference 1).

There is technology of forming a hole which reaches a surface electrode in the back surface position corresponding to the device side external electrode part by dry etching, giving metal plating films to the side wall and the back surface side circumference of the hole, and doing injection by pressure welding of the metal bumps of another semiconductor chip stacked at the upper stage side inside the through hole to which the plating film was given in the chip multi-layer structure which arranged the interposer chip for connecting between up-and-down chips in the middle of different up and down semiconductor chips (for example, refer to Patent Reference 2).

[Patent Reference 1] Japanese patent laid-open No. 2000-286304

[Patent Reference 2] Japanese patent laid-open No. 2006-210745

### SUMMARY OF THE INVENTION

In recent years, SIP (System In Package) technology attracts attention as technology of stacking a plurality of semiconductor chips (it also merely being henceforth called a chip) by which an integrated circuit is mounted in many stages on a wiring substrate, and realizing a high-speed and highly efficient system with small size and a thin shape. In it, development of the technology which flip-chip bonds the chip of the first stage on the wiring substrate, and connects between the chips after the second stage stacked on this chip by injection by pressure welding (calking) using a penetration electrode (hole-like electrode) is furthered. This structure is also called three-dimensional multi-layer structure.

In three-dimensional multi-layer structure, a through hole (hole-like electrode) is formed in a chip, further a part of bumps (projection-like electrode) formed in the chip at the side of the upper stage among the stacked chips are embedded at the through hole of the chip at the side of a lower stage, and, hereby the chip at the side of a lower stage and the chip at the side of the upper stage are electrically connected.

When flip-chip bonding the chip of the first stage in three-dimensional multi-layer structure, as shown in the comparative example of FIG. 33, by so-called gold-soldering connection which does soldering connection of the gold bump, a chip constitutes a convex warp in the direction opposite to the bump under the influence of heat. That is, with the wiring substrate and the chip, since the materials differ, coefficients of thermal expansion differ, and the chip constitutes a convex warp further according to the thermal contraction difference at the time of the chip returning to normal temperature, since the thickness is as thin as about 50 μm. As a result, as shown in FIG. 33, it is a problem that lamination of the chip after the second stage becomes difficult.

Since the chip with which a coefficient of thermal expansion differs from the wiring substrate is mounted, the layout design of a pad which took into consideration the drift of the bump pitch at the time of thermal contraction is required beforehand at the substrate side. However, in the multi-piece substrate which has a plurality of product formation regions, when an eye slip failure occurs, it differs from the amount of drifts beforehand computed from thermal expansion coefficient difference. Therefore, since the actually generated amounts of drifts of a pad also differ, it is a problem for a layout design to be difficult.

As shown in the comparative example of FIG. 34, how to stack only the chips by injection by pressure welding beforehand, and mount in a wiring substrate collectively is also considered, but hole part 3e for doing injection by pressure welding of the bump is needed for the wiring substrate in this case. However, as for forming hole part 3e, there is a problem that the fiber of a glass cloth is exposed and plating stops attaching to the wiring substrate, etc., and it is very difficult. When a flip chip connecting method is applied, the heat for doing melting of the solder is applied from the chip side, but in a laminating condition, it is a problem that heat is not easily transmitted to a gold-solder interface when heat is applied from the chip side.

An example of the lamination mounting module is disclosed by the Patent Reference 1 (Japanese patent laid-open No. 2000-286304) at the FIG. 5. In the assembly when forming stud bump 212 of the second stage on semiconductor element 100 as shown in FIG. 5 (2) after mounting the chip (semiconductor element 100) of the first stage on substrate 200 in FIG. 5 (1), carrying out by wire bonding is shown. At the time of wire bonding, substrate 200 and semiconductor element 100 are heated to high temperature in the state where they are connected via projection electrode 202. In that case, it seems that it will become the same state of the phenomenon shown in the comparative example of the FIG. 33 of the present invention, and a convex warp is formed in semiconductor element 100 by the difference of the coefficient of thermal expansion of semiconductor element 100 and substrate 200, and lamination of the chip after the second stage becomes difficult according to it.

It is disclosed that the chip of the first stage is mounted by the flip-chip bonding by gold-soldering connection in the Patent Reference 2 (Japanese patent laid-open No. 2006-210745). It will be in the same state as the phenomenon shown in the comparative example of the FIG. 33 of the present invention, and the convex warp is formed in the chip of the first stage, and lamination of the chip after the second stage becomes difficult.

A purpose of the present invention is to offer the technology which can improve the quality and reliability of a semiconductor device by eliminating a warp of a chip and performing a chip-stack.

Another purpose of the present invention is to offer the technology in which the design pattern of a wiring substrate can be performed easily The above-described and the other purposes and novel features of the present invention will become apparent from the description herein and accompanying drawings.

Of the inventions disclosed in the present application, typical ones will next be summarized briefly.

Namely, the present invention comprises a step which connects the first gold bump on a plurality of electrodes of a wiring substrate while heating, and a step which injects the first gold bump on the wiring substrate under normal temperature into the main surface side first hole-like electrode of the first semiconductor chip by pressure welding after the step which connects the first gold bump, and flip-chip bonds the first semiconductor chip at the wiring substrate. Further, a step in which injecting the second gold bump of the second semiconductor chip is done under normal temperature into the back surface side first hole-like electrode of the first semiconductor chip by pressure welding, and which stacks the second semiconductor chip on the first semiconductor chip is comprised.

Advantages achieved by some of the most typical aspects of the invention disclosed in the present application will be briefly described below.

The first gold bump is connected on a plurality of electrodes of the wiring substrate, heating, injection of the first gold bump on the wiring substrate is done by pressure welding under normal temperature after that into the main surface side first hole-like electrode of the first semiconductor chip, and flip-chip bonding of the first semiconductor chip is made. Then, injection of the second gold bump of the second semiconductor chip is done by pressure welding under normal temperature into the back surface side first hole-like electrode of the first semiconductor chip, and the second semiconductor chip is stacked on the first semiconductor chip. Therefore, a chip-stack can be performed under normal temperature. As a result, since the semiconductor chip after the second stage can be stacked in the state where there is no warp in the semiconductor chip of the first stage, injection of the gold bump of the semiconductor chip at the side of the upper stage can fully be done by pressure welding into the hole-like electrode of the semiconductor chip at the side of the lower stage. The quality and reliability of the semiconductor device can be improved.

Since the chip-stack can be performed under normal temperature, the pattern design in consideration of a drift of the bump pitch of the wiring substrate becomes unnecessary and the pattern design of the wiring substrate can be made easy.

### BRIEF DESCRIPTION OF THE DRAWINGS

FIG. 1 is a cross-sectional view showing an example of the structure of the semiconductor device of Embodiment 1 of the present invention;

FIG. 2 is a process-flow chart showing an example of the manufacturing method of the semiconductor device shown in FIG. 1;

FIG. 3 is a plan view showing an example of the structure of a wiring substrate used in the manufacturing method of the semiconductor device shown in FIG. 1;

FIG. 4 is a cross-sectional view showing an example of the structure cut along the A-A line shown in FIG. 3;

FIG. 5 is a plan view showing an example of the structure of the bump mount condition in the manufacturing method of the semiconductor device shown in FIG. 1;

FIG. 6 is a cross-sectional view showing an example of the structure cut along the A-A line shown in FIG. 5;

FIG. 7 is a plan view showing an example of the structure at the time of first stage chip mounting in the manufacturing method of the semiconductor device shown in FIG. 1;

FIG. 8 is a cross-sectional view showing an example of the structure cut along the A-A line shown in FIG. 7;

FIG. 9 is a plan view showing an example of the structure at the time of second stage chip mounting in the manufacturing method of the semiconductor device shown in FIG. 1;

FIG. 10 is a cross-sectional view showing an example of the structure cut along the A-A line of FIG. 9;

FIG. 11 is a plan view showing an example of the structure after under-fill filling in the manufacturing method of the semiconductor device shown in FIG. 1;

FIG. 12 is a cross-sectional view showing an example of the structure cut along the A-A line of FIG. 11;

FIG. 13 is a plan view showing an example of the structure after the resin seal in the manufacturing method of the semiconductor device shown in FIG. 1;

FIG. 14 is a cross-sectional view showing an example of the structure cut along the A-A line of FIG. 13;

FIG. 15 is a cross-sectional view showing the structure of the principal part of the semiconductor device of the modification of Embodiment 1 of the present invention;

FIG. 16 is a cross-sectional view showing the modification of the manufacturing method of the semiconductor device of Embodiment 1 of the present invention;

FIG. 17 is a cross-sectional view showing an example of the structure of the semiconductor device of Embodiment 2 of the present invention;

FIG. 18 is a process-flow chart showing an example of the manufacturing method of the semiconductor device shown in FIG. 17;

FIG. 19 is a plan view showing an example of the structure of a wiring substrate used in the manufacturing method of the semiconductor device shown in FIG. 17;

FIG. 20 is a cross-sectional view showing an example of the structure cut along the A-A line of FIG. 19;

FIG. 21 is a plan view showing an example of the structure of the bump mount condition in the manufacturing method of the semiconductor device shown in FIG. 17;

FIG. 22 is a cross-sectional view showing an example of the structure cut along the A-A line of FIG. 21;

FIG. 23 is a plan view showing an example of the structure at the time of first stage chip mounting in the manufacturing method of the semiconductor device shown in FIG. 17;

FIG. 24 is a cross-sectional view showing an example of the structure cut along the A-A line of FIG. 23;

FIG. 25 is a plan view showing an example of the structure at the time of second stage chip mounting in the manufacturing method of the semiconductor device shown in FIG. 17;

FIG. 26 is a cross-sectional view showing an example of the structure cut along the A-A line of FIG. 25;

FIG. 27 is a plan view showing an example of the structure after under-fill filling in the manufacturing method of the semiconductor device shown in FIG. 1;

FIG. 28 is a cross-sectional view showing an example of the structure cut along the A-A line of FIG. 27;

FIG. 29 is a plan view showing an example of the structure at the time of third stage chip mounting in the manufacturing method of the semiconductor device shown in FIG. 17;

FIG. 30 is a cross-sectional view showing an example of the structure cut along the A-A line of FIG. 29;

FIG. 31 is a plan view showing an example of the structure after the resin seal in the manufacturing method of the semiconductor device shown in FIG. 17;

FIG. 32 is a cross-sectional view showing an example of the structure cut along the A-A line of FIG. 31;

FIG. 33 is a cross-sectional view showing the chip warp structure in the manufacturing method of the semiconductor device of a comparative example;

FIG. 34 is a cross-sectional view showing the manufacturing method of the semiconductor device of a comparative example; and

FIG. 35 is a cross-sectional view showing the manufacturing method of the semiconductor device of a comparative example.

### DETAILED DESCRIPTION OF THE PREFERRED EMBODIMENTS

In the following embodiments, except the time when especially required, explanation of identical or similar part is not repeated in principle.

In the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated.

In the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number.

Hereafter, embodiments of the invention are explained in detail based on drawings. In all the drawings for describing the embodiments, members of a like function will be identified by like reference numerals and overlapping descriptions will be omitted. Hatching may be attached even if it is a perspective view and a plan view, in order to make a drawing intelligible.

### Embodiment 1

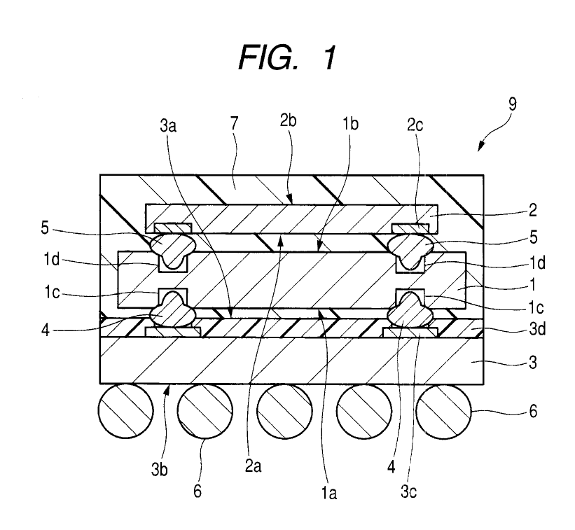

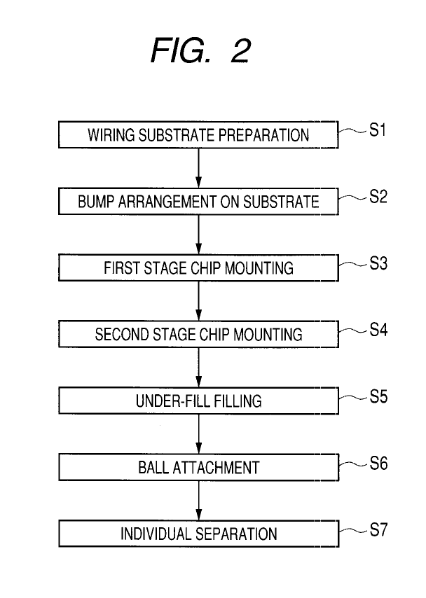

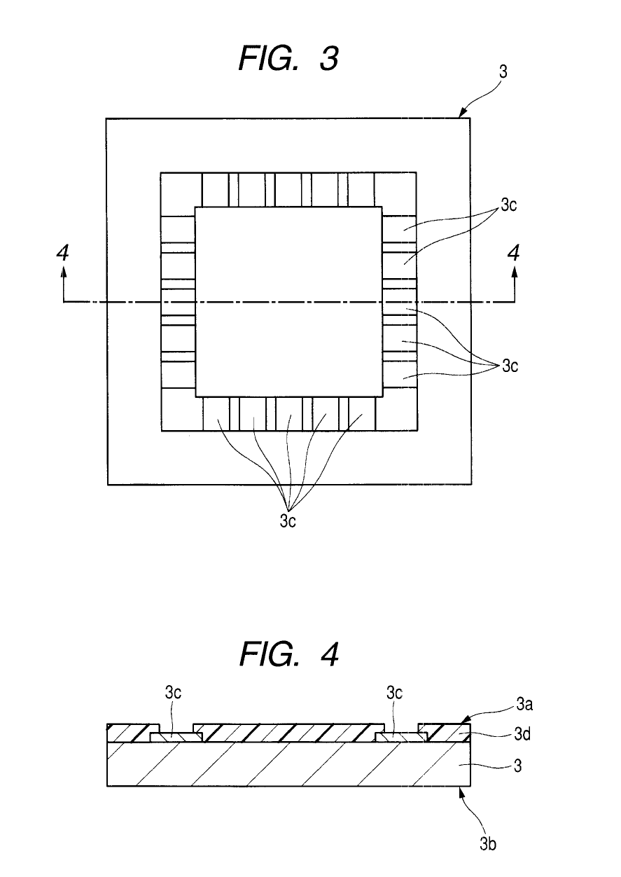

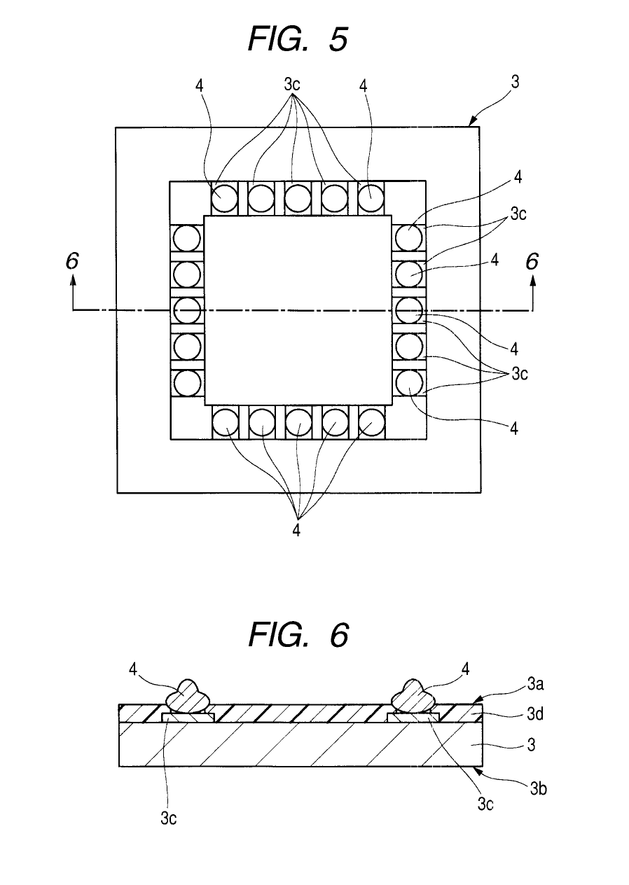

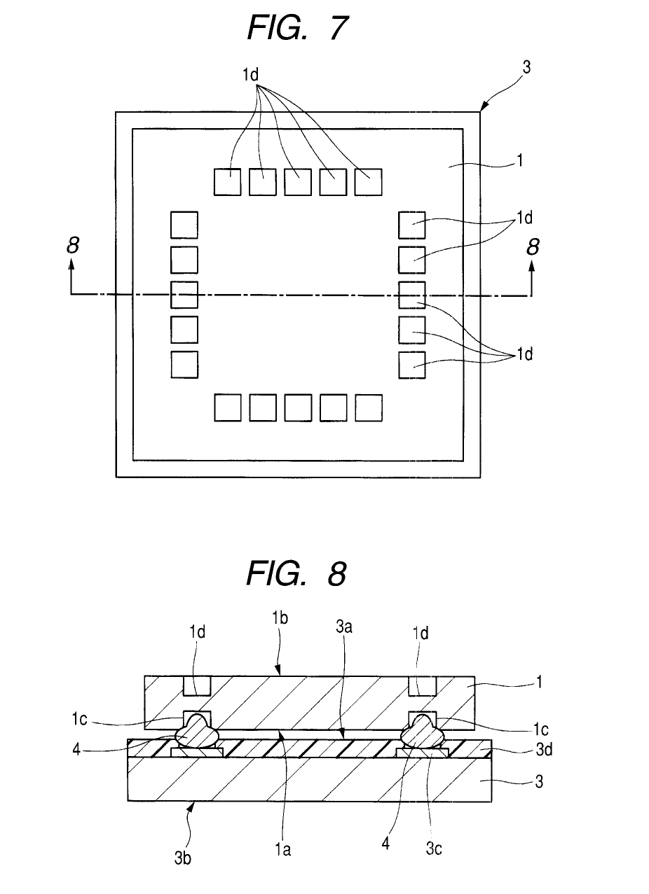

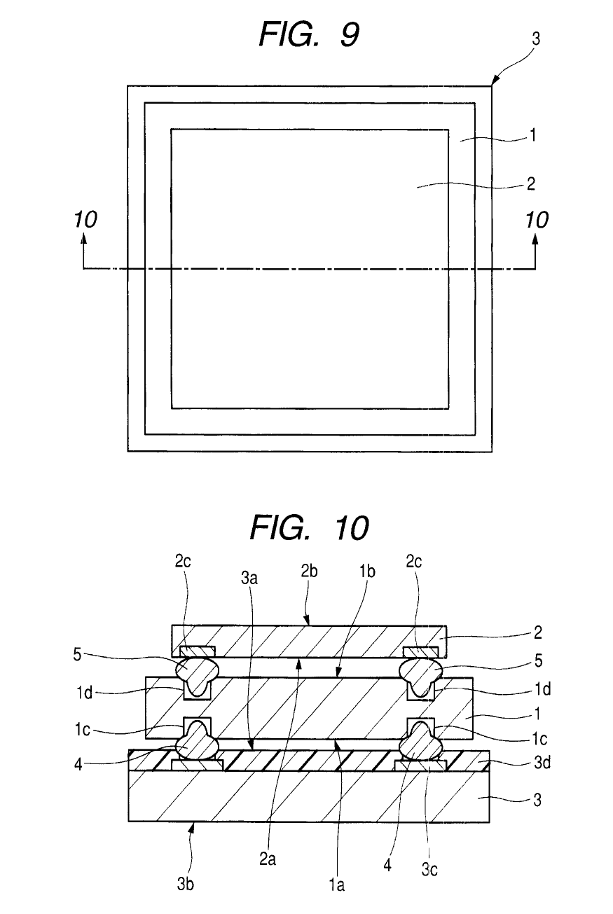

FIG. 1 is a cross-sectional view showing an example of the structure of the semiconductor device of Embodiment 1 of the present invention, FIG. 2 is a process-flow chart showing an example of the manufacturing method of the semiconductor device shown in FIG. 1, FIG. 3 is a plan view showing an example of the structure of a wiring substrate used in the manufacturing method of the semiconductor device shown in FIG. 1, and FIG. 4 is a cross-sectional view showing an example of the structure cut along the A-A line shown in FIG. 3. And, FIG. 5 is a plan view showing an example of the structure of the bump mount condition in the manufacturing method of the semiconductor device shown in FIG. 1, and FIG. 6 is a cross-sectional view showing an example of the structure cut along the A-A line shown in FIG. 5. Further, FIG. 7 is a plan view showing an example of the structure at the time of first stage chip mounting in the manufacturing method of the semiconductor device shown in FIG. 1, FIG. 8 is a cross-sectional view showing an example of the structure cut along the A-A line shown in FIG. 7, FIG. 9 is a plan view showing an example of the structure at the time of second stage chip mounting in the manufacturing method of the semiconductor device shown in FIG. 1, and FIG. 10 is a cross-sectional view showing an example of the structure cut along the A-A line of FIG. 9.

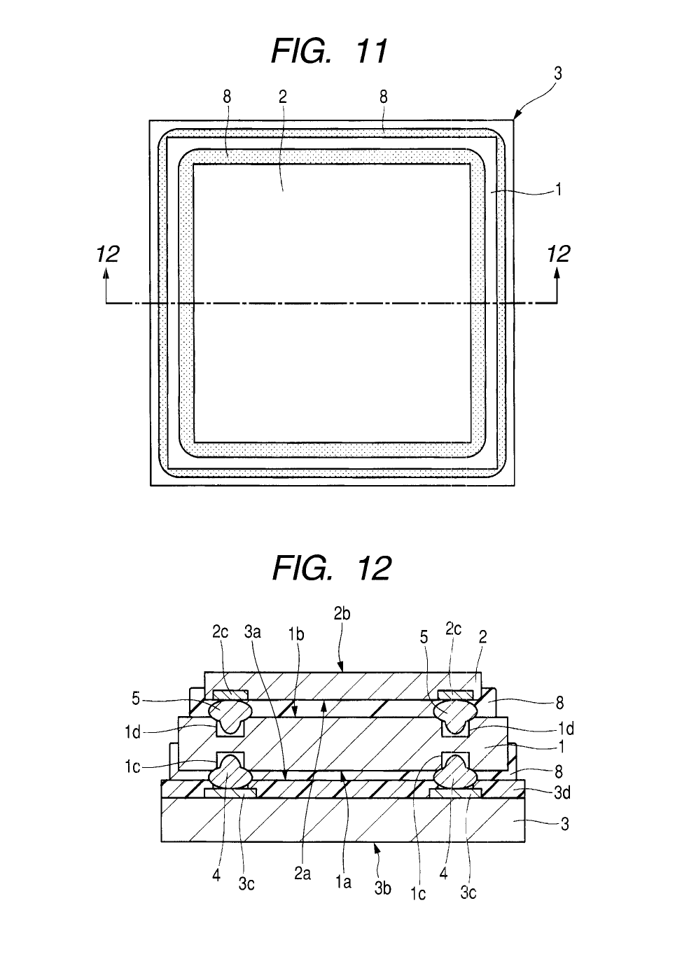

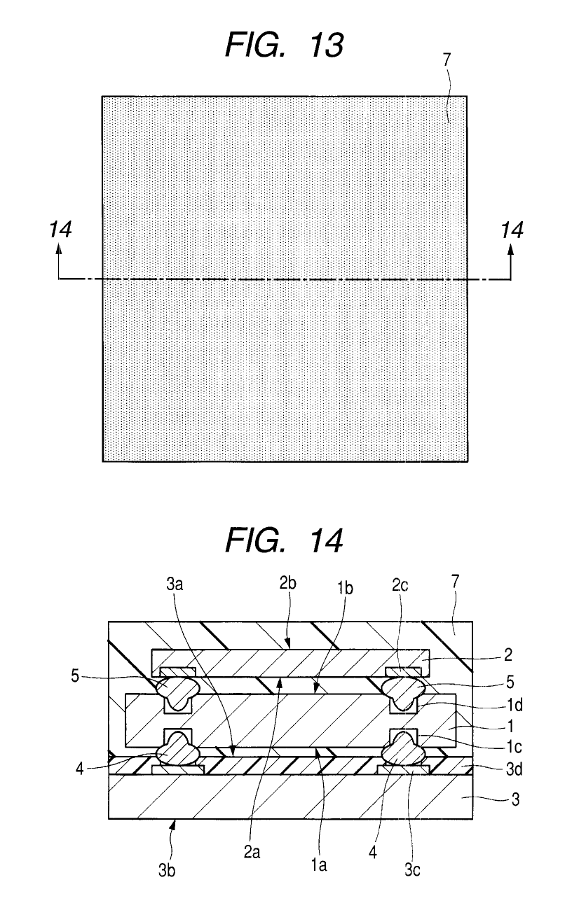

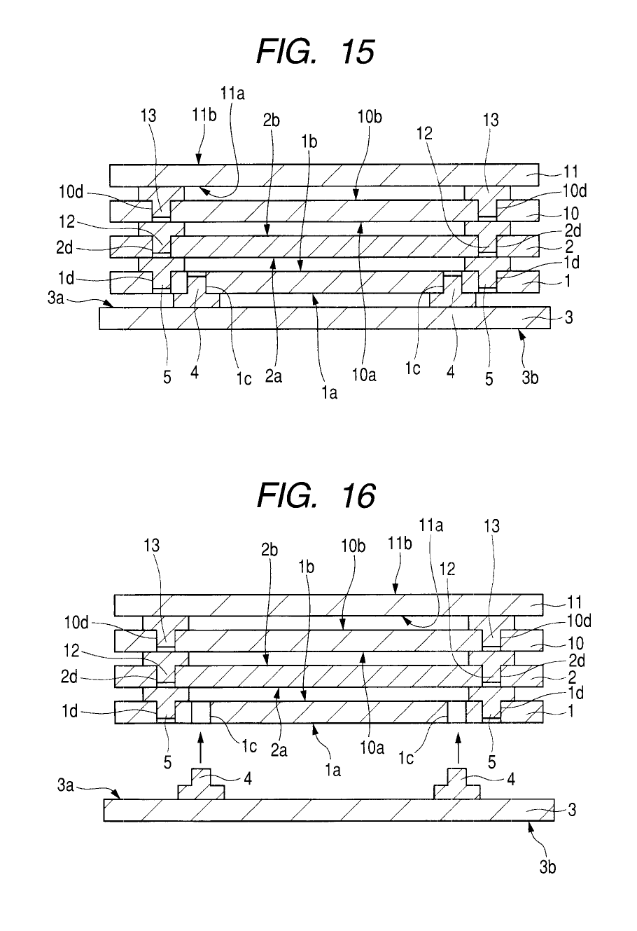

And, FIG. 11 is a plan view showing an example of the structure after under-fill filling in the manufacturing method of the semiconductor device shown in FIG. 1, FIG. 12 is a cross-sectional view showing an example of the structure cut along the A-A line of FIG. 11, FIG. 13 is a plan view showing an example of the structure after the resin seal in the manufacturing method of the semiconductor device shown in FIG. 1, and FIG. 14 is a cross-sectional view showing an example of the structure cut along the A-A line of FIG. 13. Further, FIG. 15 is a cross-sectional view showing the structure of the principal part of the semiconductor device of the modification of Embodiment 1 of the present invention, and FIG. 16 is a cross-sectional view showing the modification of the manufacturing method of the semiconductor device of Embodiment 1 of the present invention.

The semiconductor device of Embodiment 1 is semiconductor package 9 of the 2 stages of chip multi-layer structure by which the semiconductor chip of the first stage was mounted via the gold bump fixed on wiring substrate 3, and the semiconductor chip of the second stage was further stacked via the gold bump on this semiconductor chip.

The structure of semiconductor package 9 shown in FIG. 1 is explained. Wiring substrate 3 on which a plurality of electrodes 3c were formed in main surface 3a, first semiconductor chip 1 mounted via first gold bump 4 on wiring substrate 3, second semiconductor chip 2 stacked via second gold bump 5 on first semiconductor chip 1, sealing body 7 which does the resin seal of each semiconductor chip, and a plurality of solder balls 6 formed in back surface 3b of wiring substrate 3 are comprised. That is, a plurality of solder balls 6 which are external terminals are formed in back surface 3b of wiring substrate 3, and it is semiconductor package 9 of the structure same in external appearance as BGA (Ball Grid Array).

First semiconductor chip 1 is mounted on wiring substrate 3 so that the main surface 1a may face with main surface 3a of wiring substrate 3 turning to the substrate side, therefore back surface 1b has turned to the upper part. Second semiconductor chip 2 is also stacked via second gold bump 5 on first semiconductor chip 1, and the main surface 2a is turned to a lower part (first semiconductor chip 1 side), and back surface 2b is turned up, and it is stacked. In the case, as for second gold bump 5 of the second stage connected to pad (surface electrode) 2c of main surface 2a, the part is embedded at the back surface side hole-like electrode 1d of first semiconductor chip 1 of the first stage, and second gold bump 5 and the back surface side hole-like electrode 1d are electrically connected.

Here, semiconductor package 9 of Embodiment 1 is a thing of the three-dimensional multi-layer structure which connects the wiring between chips and between a chip and a substrate in three dimensions. That is, first semiconductor chip 1 of the first stage is mounted via a gold bump on wiring substrate 3. Pressure welding injection (calking) of the gold bump is done to the hole-like electrode of first semiconductor chip 1, and second semiconductor chip 2 of the second stage is stacked on first semiconductor chip 1. While second semiconductor chip 2 is stacked on first semiconductor chip 1 by this, first semiconductor chip 1 and second semiconductor chip 2 are electrically connected via a gold bump by it.

In the three-dimensional multi-layer structure of semiconductor package 9 of Embodiment 1, main surface side hole-like electrode (main surface side first hole-like electrode) 1c is formed in main surface 1a of first semiconductor chip 1 of the first stage, and back surface side hole-like electrode (back surface side first hole-like electrode) 1d is further formed in back surface 1b. Main surface side hole-like electrode 1c is a hole-like electrode opened at the main surface 1a side at least, and, on the other hand, a back surface side hole-like electrode 1d is a hole-like electrode opened at the back surface 1b side at least. Corresponding a main surface side hole-like electrode 1c and a corresponding back surface side hole-like electrode 1d are electrically connected inside the substrate.

Hereby when stacking chips, first semiconductor chip 1 at the side of a lower stage and second semiconductor chip 2 at the side of the upper stage are electrically connected by embedding a part of second gold bumps 5 formed in second semiconductor chip 2 at the side of the upper stage to the back surface side hole-like electrode 1d of first semiconductor chip 1 at the side of a lower stage.

At semiconductor package 9, first semiconductor chip 1 of the first stage is also mounted by injecting (calking) the first gold bump 4 beforehand connected on wiring substrate 3 into main surface side hole-like electrode 1c of first semiconductor chip 1 by pressure welding.

Before first semiconductor chip 1 mounting, in the state which heated wiring substrate 3 at a temperature lower than Tg temperature (softening point) of wiring substrate 3, ultrasonic connection of the first gold bump 4 was made at electrode 3c on main surface 3a of wiring substrate 3. Here, as a temperature which heats wiring substrate 3, it is 120° C., for example. The gold plating layer is formed in electrode 3c of wiring substrate 3.

Connection with first gold bump 4 of first semiconductor chip 1, and the connection with first semiconductor chip 1 of second gold bump 5 on second semiconductor chip 2 are made by injecting (calking) the gold bump into the hole-like electrode of first semiconductor chip 1 by pressure welding, respectively Pressure welding injection into a hole-like electrode of each gold bump is performed under the normal temperature process which is not heated intentionally in the case.

First semiconductor chip 1 and second semiconductor chip 2 are formed with silicon, and have main surfaces (the circuit formation surface, element formation surface) 1a and 2a, and back surface 1b and 2b mutually located in the opposite side, respectively for example. The plane form which intersects a thickness direction is rectangular shape, respectively.

The plane form to which wiring substrate 3 intersects the direction of board thickness is rectangular shape. Solder resist 3d which is an insulation film is formed in the front surface.

Sealing body 7 is what was made to cure resin for sealing, such as thermosetting resin of an epoxy system, and was formed, for example.

Next, the manufacturing method of the semiconductor device of Embodiment 1 is explained using the manufacture process-flow chart shown in FIG. 2.

First, the wiring substrate preparation shown in Step S1 of FIG. 2 is made. Here, as shown in FIG. 3 and FIG. 4, wiring substrate 3 which has main surface (substrate main surface) 3a, and back surface (substrate rear) 3b opposite to main surface 3a and by which a plurality of electrodes 3c were formed in main surface 3a is prepared. The gold plating layer is formed on a plurality of electrodes 3c.

Then, as shown in FIG. 1, first semiconductor chip 1 which has main surface (first chip main surface) 1a, and back surface 1b opposite to main surface 1a (first chip back surface), in which main surface side hole-like electrode 1c opened at the main surface 1a side and the back surface side hole-like electrode 1d opened at the back surface 1b side are formed, and to which a main surface side hole-like electrode 1c and the back surface side hole-like electrode 1d were furthermore electrically connected by internal wiring is prepared.

On the other hand, second semiconductor chip 2 which has main surface (second chip main surface) 2a, and back surface (second chip back surface) 2b opposite to main surface 2a and with which second gold bump 5 has been arranged on pad 2c of main surface 2a is prepared. Second gold bump 5 is a stud bump, and is a bump connected using wire bonding on pad 2c of main surface 2a of second semiconductor chip 2. In the case, second gold bump 5 is formed so that second gold bump's 5 diameter may become larger than the hole size of the back surface side hole-like electrode 1d of first semiconductor chip 1. Namely to the degree in which injection by pressure welding into the back surface side hole-like electrode 1d is possible regarding second gold bump 5, second gold bump's 5 diameter is formed more greatly than the hole size of the back surface side hole-like electrode 1d of first semiconductor chip 1.

Then, as shown in Step S2, FIG. 5, and FIG. 6, first gold bump 4 is connected on a plurality of electrodes 3c of main surface 3a of wiring substrate 3. Here, first gold bump 4 is arranged by ultrasonic connection at electrode 3c on main surface 3a of wiring substrate 3, where wiring substrate 3 is heated at a temperature lower than Tg temperature (softening point) of wiring substrate 3. As a temperature which heats wiring substrate 3, it is 120° C., for example. The gold plating layer is formed in electrode 3c of wiring substrate 3.

First gold bump 4 is a stud bump formed using wire bonding as well as second gold bump 5. In the case, first gold bump 4 is formed so that first gold bump's 4 diameter may become larger than the hole size of main surface side hole-like electrode 1c of first semiconductor chip 1. That is, in a degree in which injection by pressure welding into main surface side hole-like electrode 1c is possible about first gold bump 4, first gold bump's 4 diameter is formed more greatly than the hole size of main surface side hole-like electrode 1c of first semiconductor chip 1.

Then, first stage chip mounting which is shown in Step S3 of FIG. 2 is performed. Here, as shown in FIG. 7 and FIG. 8, main surface 1a of first semiconductor chip 1 in which main surface side hole-like electrode 1c and the back surface side hole-like electrode 1d were formed, and main surface 3a of wiring substrate 3 are disposed to face first. That is, main surface 1a of first semiconductor chip 1 is disposed to face on main surface 3a of wiring substrate 3 in main surface 3a of wiring substrate 3.

Then, injection by pressure welding of the first gold bump 4 on wiring substrate 3 corresponding to this is done in the atmosphere of normal temperature into main surface side hole-like electrode 1c of first semiconductor chip 1, and flip-chip bonding of the first semiconductor chip 1 is made. Here, as shown in FIG. 8, in the atmosphere of normal temperature, injection by pressure welding (calking processing) is done into main surface side hole-like electrode 1c of first semiconductor chip 1, and first gold bump 4 on wiring substrate 3 is embedded at it.

Since first gold bump 4 is formed in the case so that the diameter may become large slightly from the hole size of main surface side hole-like electrode 1c, injection by pressure welding (calking processing) of the first gold bump 4 can be done to main surface side hole-like electrode 1c. First semiconductor chip 1 can be mounted on wiring substrate 3 by this.

The normal temperature is a temperature lower enough than the temperature (120˜150° C.) at the time of doing bonding of the first gold bump 4 to wiring substrate 3, for example, and when it has another way of speaking, temperature is a temperature as it is which is not applied intentionally. That is, when connecting first gold bump 4 to wiring substrate 3, it is heating by 120˜150° C., for example. On the other hand, especially when flip-chip bonding the first semiconductor chip 1 by injection by pressure welding, it is carried out in the normal temperature, without heating.

Therefore, in the manufacturing method of the semiconductor device of Embodiment 1, at the time of flip-chip bonding of first semiconductor chip 1 which is a chip of the first stage, it can be connected without using a heating process.

Then, second stage chip mounting which is shown in Step S4 of FIG. 2 is performed. First, as shown in FIG. 9 and FIG. 10, main surface 2a of second semiconductor chip 2 is disposed to face on back surface 1b of first semiconductor chip 1. That is, main surface 2a of second semiconductor chip 2 is disposed to face at the back surface 1b of first semiconductor chip 1 on back surface 1b of first semiconductor chip 1.

Then, injection by pressure welding of the second gold bump 5 connected to second semiconductor chip 2 is done in the atmosphere of normal temperature into the back surface side hole-like electrode 1d of first semiconductor chip 1, and second semiconductor chip 2 is stacked on first semiconductor chip 1. Here, as shown in FIG. 10, in the atmosphere of normal temperature, injection by pressure welding (calking processing) is done into the back surface side hole-like electrode 1d of first semiconductor chip 1, and second gold bump 5 on second semiconductor chip 2 is embedded at it.

Since second gold bump 5 is also formed in the case so that the diameter may become large slightly from the hole size of a back surface side hole-like electrode 1d, injection by pressure welding (calking processing) of the second gold bump 5 can be done into a back surface side hole-like electrode 1d. Second semiconductor chip 2 can be mounted on first semiconductor chip 1 by this.

Also in the mounting step of the semiconductor chip of the second stage, the normal temperature is a temperature lower enough than the temperature (120˜150° C.) at the time of doing bonding of the first gold bump 4 to wiring substrate 3, for example. When it has another way of speaking, the temperature is a temperature as it is which is not applied intentionally That is, when connecting first gold bump 4 to wiring substrate 3, they are heated to 120˜150° C., for example. On the other hand, also when second semiconductor chip 2 is mounted on first semiconductor chip 1 by injection by pressure welding, it is carried out under normal temperature, without heating especially.

Therefore, also in second semiconductor chip 2 which is a semiconductor chip of the second stage mounting, flip-chip bonding can be made on first semiconductor chip 1 without using a heating process.

Then, under-fill filling shown in Step S5 of FIG. 2 is performed. Here, as shown in FIG. 11 and FIG. 12, between first semiconductor chip 1 and wiring substrates 3 and the circumference of first semiconductor chip 1 are filled up with under-fill 8 (resin). Furthermore, between second semiconductor chip 2 and first semiconductor chips 1 and the circumference of second semiconductor chip 2 are filled up with under-fill 8 (resin). Baking processing of under-fill 8 is performed after filling. The bake temperature of under-fill 8 is about 150° C., for example.

About filling of under-fill 8, when there are few laminations of a semiconductor chip, after mounting the semiconductor chip of the first stage (after the termination of step S3 of FIG. 2), it may be filled up with under-fill 8 to first semiconductor chip 1.

Instead of filling of under-fill 8, as shown in FIG. 13 and FIG. 14, a resin seal may be performed and sealing body 7 may be formed. That is, after doing two or more stages (Embodiment 1 two stages) lamination of the semiconductor chip on wiring substrate 3, the resin seal of the semiconductor chip of two or more stages and the gold bump (first gold bump 4 and second gold bump 5) may be done, and sealing body 7 may be formed.

Then, ball attachment shown in Step S6 is performed. Here, as shown in FIG. 1, solder balls 6 which are a plurality of external terminals are joined to back surface 3b of wiring substrate 3. Individual separation shown in Step S7 is performed, and it becomes assembly completion of semiconductor package 9 which is SIP.

According to the manufacturing method of the semiconductor device of Embodiment 1, ultrasonic connection of the first gold bump 4 is made, heating wiring substrate 3 on a plurality of electrodes 3c of wiring substrate 3. Then, injection by pressure welding (calking processing) of the first gold bump 4 on wiring substrate 3 is done into main surface side hole-like electrode 1c of first semiconductor chip 1 in the atmosphere of normal temperature, and first semiconductor chip 1 is mounted on wiring substrate 3. Then, since injection by pressure welding of the second gold bump 5 of second semiconductor chip 2 is done in the atmosphere of normal temperature into the back surface side hole-like electrode 1d of first semiconductor chip 1 and second semiconductor chip 2 is stacked on first semiconductor chip 1, a chip-stack can be performed in a normal temperature process.

Since a semiconductor chip different from the coefficient of thermal expansion of wiring substrate 3 is not arranged on main surface 3a of wiring substrate 3 even if wiring substrate 3 expands under the influence of heat which heats wiring substrate 3, when first gold bump 4 is fixed to electrode 3c of wiring substrate 3, a warp does not happen in wiring substrate 3. Here, although first gold bump 4 is arranged at wiring substrate 3, this gold bump will not become a factor according to which wiring substrate 3 warps, even if the material is different from coefficient of thermal expansion of wiring substrate 3, since it is very small when seeing from wiring substrate 3 or a semiconductor chip.

That is, a plurality of first gold bumps 4 are connected on wiring substrate 3, heating. Then, after returning to the atmosphere of normal temperature, to first gold bump 4, injection by pressure welding is done and first semiconductor chip 1 of the first stage is mounted. When connecting the semiconductor chip of the first stage or the second stage by pressure welding injection by furthermore stacking second semiconductor chip 2 of the second stage on first semiconductor chip 1 in the atmosphere of normal temperature, it can be carried out under normal temperature (state where heat is not applied intentionally).

Hereby second semiconductor chip 2 after the second stage can be stacked in the state where there is no warp in first semiconductor chip 1 of the first stage. As a result, injection by pressure welding of the second gold bump 5 of second semiconductor chip 2 at the side of the upper stage to stack can be done surely enough into the back surface side hole-like electrode 1d of first semiconductor chip 1 at the side of a lower stage. Thereby the quality and reliability of semiconductor package (semiconductor device) 9 can be improved.

Since a chip-stack can be performed in a normal temperature process, the design pattern in consideration of a drift of the bump pitch of wiring substrate 3 becomes unnecessary and the design pattern of wiring substrate 3 can be made easy.

That is, when a semiconductor chip and wiring substrate 3 are connected by a gold bump and wiring substrate 3 is restrained, the terminal position of a substrate is designed beforehand in consideration of causing a pitch drift with the difference of both coefficient of thermal expansion, when it gets cold. However, since wiring substrate 3 is not alone restrained like the manufacturing method of the semiconductor device of Embodiment 1 when heat takes at the time of connection of first gold bump 4, a bump pitch returns.

Therefore, the design pattern in consideration of a drift of the bump pitch of wiring substrate 3 becomes unnecessary and the design pattern of wiring substrate 3 can be made easy.

In semiconductor package 9 of Embodiment 1, since the interposer is not made to intervene, the thickness reduction of SIP type semiconductor package 9 is realizable.

In how to connect only a gold bump to wiring substrate 3 beforehand like the manufacturing method of the semiconductor device of Embodiment 1, in order to simplify a subsequent chip laminating process, as shown in the comparative example of FIG. 35, how to form second gold bump 5 on first semiconductor chip 1 of the opposite side in wiring substrate 3, and do injection by pressure welding one by one is also considered.

However, when second gold bump 5 is upward like the method shown in the comparative example of FIG. 35, the jig for holding first semiconductor chip 1 and second gold bump 5 will contact, and handling of a chip will become difficult. The problem that load cannot be further applied from the chip upper surface side in the case of injection by pressure welding occurs.

On the other hand, like the manufacturing method of the semiconductor device of Embodiment 1, when second gold bump 5 is formed downward to second semiconductor chip 2, handling of second semiconductor chip 2 can also be performed easily Furthermore, it can also be performed easily applying load from the chip upper surface side in the case of injection by pressure welding.

Next, the modification of Embodiment 1 is explained.

The modification shown in FIG. 15 shows structure in case first semiconductor chip 1 of the first stage on wiring substrate 3 is an interposer. That is, flip-chip bonding of the first semiconductor chip 1 of the first stage is made as an interposer on wiring substrate 3, and second semiconductor chip 2, third semiconductor chip 10, and fourth semiconductor chip 11 are stacked one by one on first semiconductor chip 1.

Flip chip connection of the first semiconductor chip 1 is made via first gold bump 4 on main surface 3a of wiring substrate 3, and second semiconductor chip 2 is stacked on first semiconductor chip 1 via second gold bump 5. Third semiconductor chip 10 is stacked on second semiconductor chip 2 via third gold bump 12, and fourth semiconductor chip 11 is further stacked on third semiconductor chip 10 via fourth gold bump 13.

Pressure welding injection (calking processing) of each gold bump used to be done to a corresponding hole-like electrode under normal temperature. That is, injection by pressure welding of the first gold bump 4 formed on wiring substrate 3 is done into main surface side hole-like electrode 1c of first semiconductor chip 1. Injection by pressure welding of the second gold bump 5 formed in second semiconductor chip 2 is done into the back surface side hole-like electrode 1d of first semiconductor chip 1. Injection by pressure welding of the third gold bump 12 formed in third semiconductor chip 10 is done into second hole-like electrode 2d of second semiconductor chip 2. Injection by pressure welding of the fourth gold bump 13 formed in fourth semiconductor chip 11 is done into third hole-like electrode 10d of third semiconductor chip 10.

Main surface side hole-like electrode 1c and the back surface side hole-like electrode 1d of first semiconductor chip 1 which is an interposer are formed to constitute a pair, and both are formed in the position which shifted to the plane direction. Hereby first semiconductor chip 1 which is an interposer can be formed thinly The pitch adjusting of the terminal of a substrate side and the terminal of a chip side can be performed by making first semiconductor chip 1 of the first stage into an interposer. Since pitch conversion can be performed between substrate-chips, it becomes possible to extend the pitch of electrode 3c for flip-chip bonding of a substrate side, and the pattern layout of a substrate can be made easy.

In the case semiconductor package 9 is SIP etc., by making first semiconductor chip 1 of the first stage into an interposer in the case of the structure where a microcomputer chip is arranged at the bottom, for example, the problem that the regions for element formation (area) will decrease in number when a plurality of hole-like electrodes are formed in a microcomputer chip, and the region for element formation runs short arises. Therefore, in a microcomputer chip, the region for element formation is fully securable by making a first stage chip into an interposer, and forming a plurality of hole-like electrodes in an interposer by using the second stage as a microcomputer chip.

Next, the modification shown in FIG. 16 does not stack a semiconductor chip one by one on wiring substrate 3 in the assembly of a semiconductor device. A semiconductor chip is beforehand stacked collectively to the highest stage in the atmosphere of normal temperature, and injection of the stacked semiconductor chip is done by pressure welding in the atmosphere of normal temperature after that at wiring substrate 3.

That is, main surface 2a of second semiconductor chip 2 is disposed to face on back surface 1b of first semiconductor chip 1. Then, in the atmosphere of normal temperature, injection by pressure welding of the second gold bump 5 of second semiconductor chip 2 is done at the back surface side hole-like electrode 1d of first semiconductor chip 1, and second semiconductor chip 2 is stacked on first semiconductor chip 1. Then, lamination of third semiconductor chip 10 and fourth semiconductor chip 11 is performed one by one by the same method.

After the completion of chip lamination, main surface 3a of wiring substrate 3 and main surface 1a of first semiconductor chip 1 are disposed to face. Then, injection by pressure welding of the first gold bump 4 heated and connected to wiring substrate 3 is done in the atmosphere of normal temperature into main surface side hole-like electrode 1c of first semiconductor chip 1, and first semiconductor chip 1—fourth semiconductor chip 11 are stacked on wiring substrate 3.

Thus, semiconductor chips are beforehand stacked collectively to the highest stage in the atmosphere of normal temperature. Then, the efficiency of an assembly can be improved by injecting the stacked semiconductor chip in the atmosphere of normal temperature at wiring substrate 3 by pressure welding.

### Embodiment 2

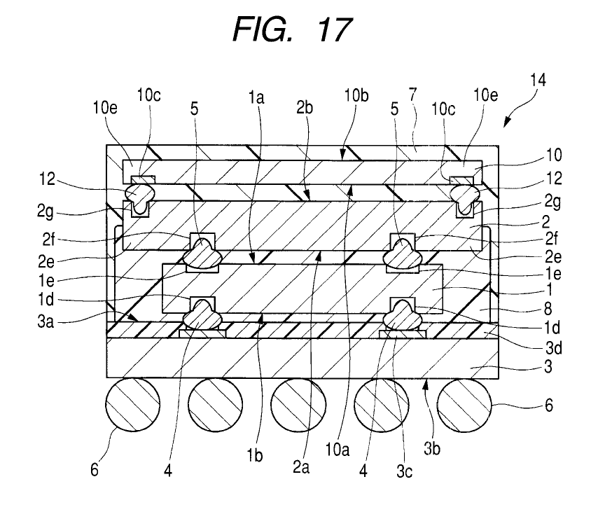

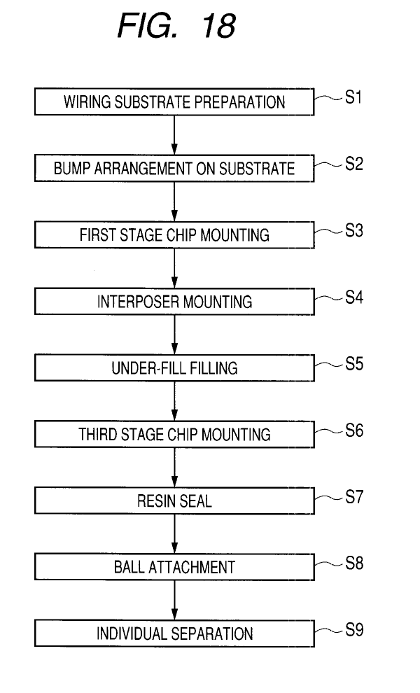

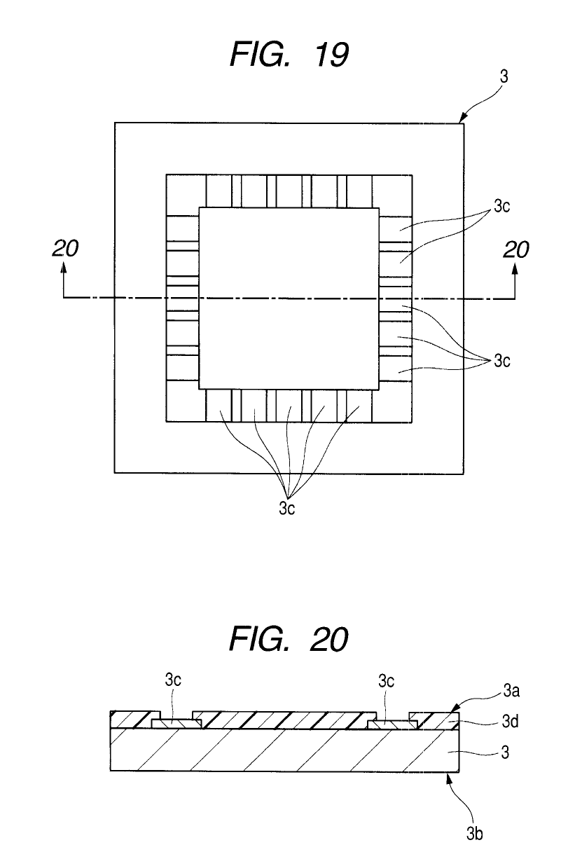

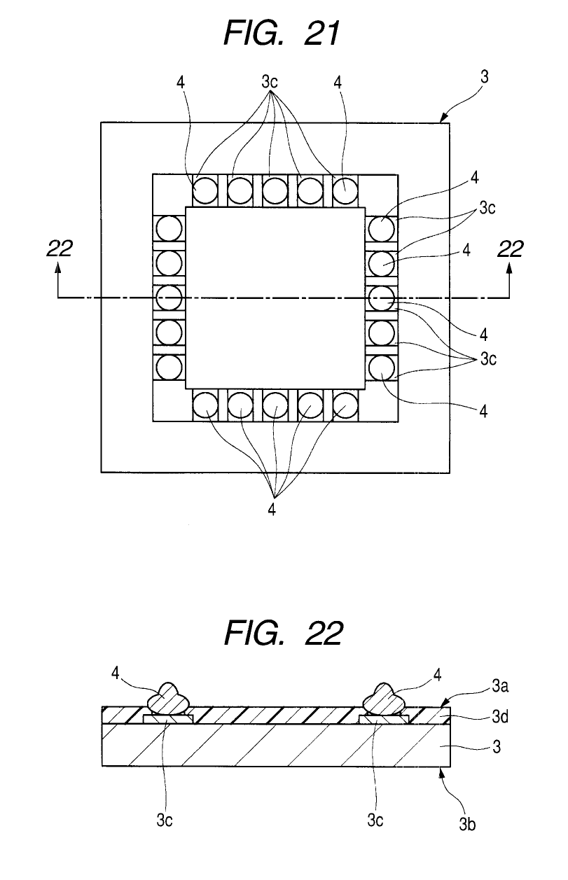

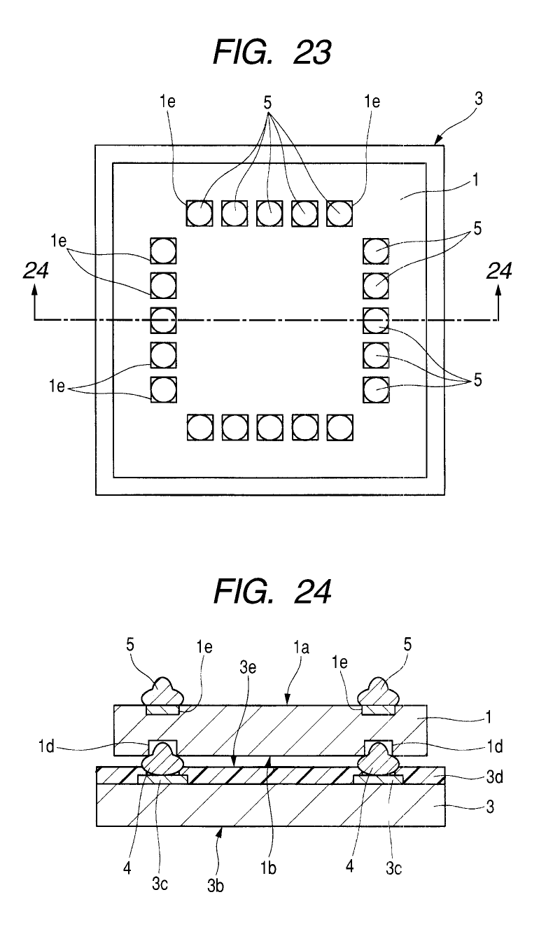

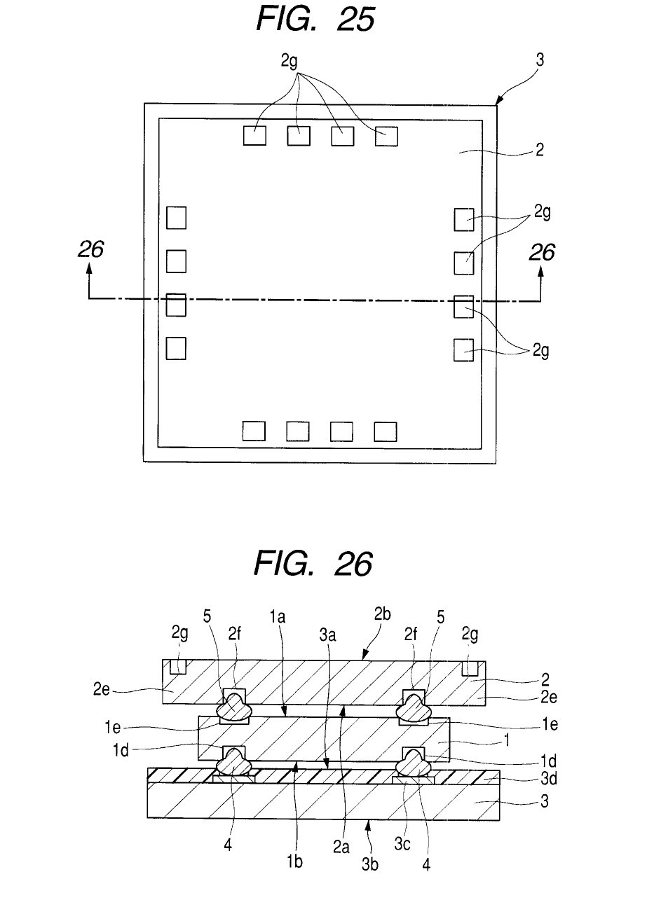

FIG. 17 is a cross-sectional view showing an example of the structure of the semiconductor device of Embodiment 2 of the present invention, FIG. 18 is a process-flow chart showing an example of the manufacturing method of the semiconductor device shown in FIG. 17, FIG. 19 is a plan view showing an example of the structure of a wiring substrate used in the manufacturing method of the semiconductor device shown in FIG. 17, and FIG. 20 is a cross-sectional view showing an example of the structure cut along the A-A line of FIG. 19. And, FIG. 21 is a plan view showing an example of the structure of the bump mount condition in the manufacturing method of the semiconductor device shown in FIG. 17, and FIG. 22 is a cross-sectional view showing an example of the structure cut along the A-A line of FIG. 21. Further, FIG. 23 is a plan view showing an example of the structure at the time of first stage chip mounting in the manufacturing method of the semiconductor device shown in FIG. 17, FIG. 24 is a cross-sectional view showing an example of the structure cut along the A-A line of FIG. 23, FIG. 25 is a plan view showing an example of the structure at the time of second stage chip mounting in the manufacturing method of the semiconductor device shown in FIG. 17, and FIG. 26 is a cross-sectional view showing an example of the structure cut along the A-A line of FIG. 25.

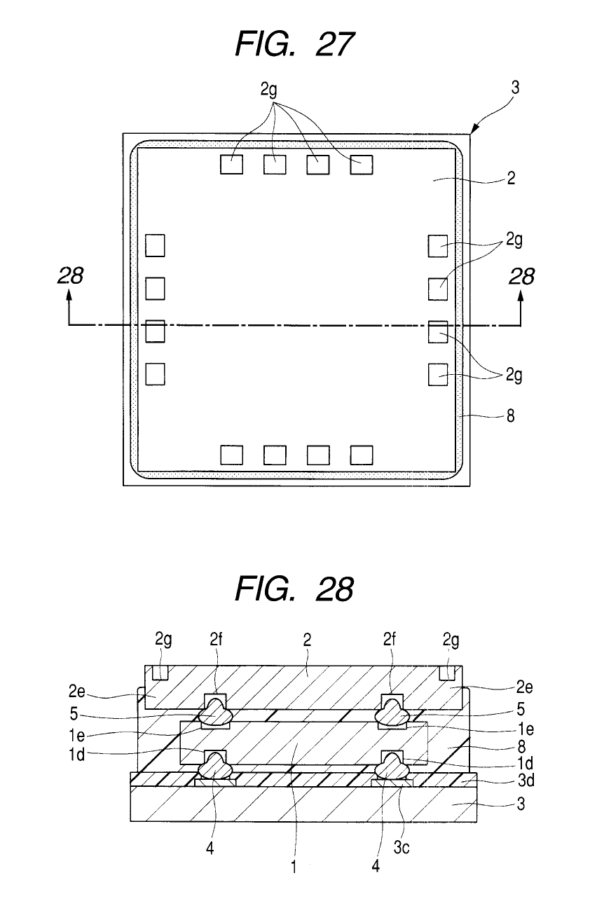

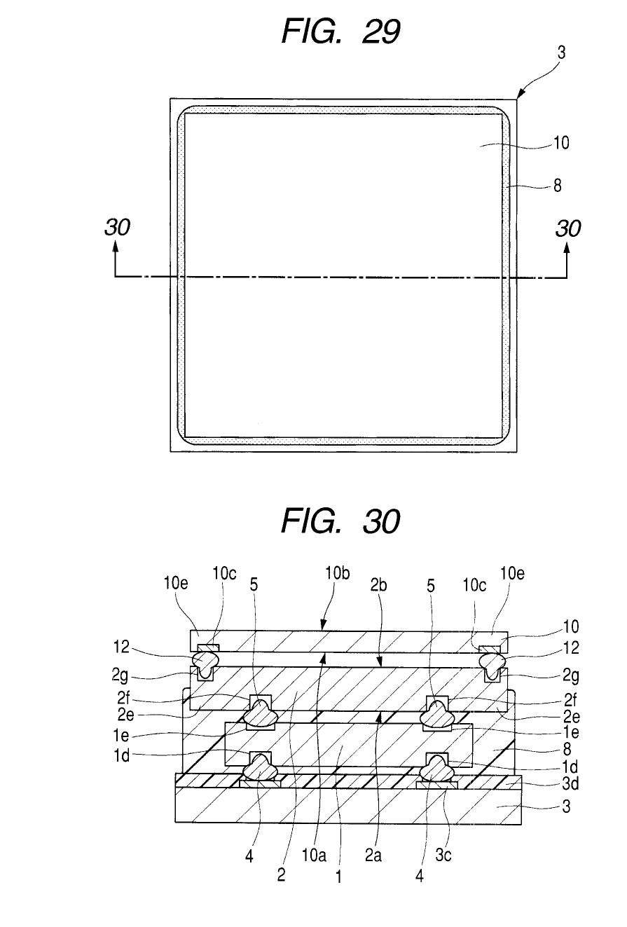

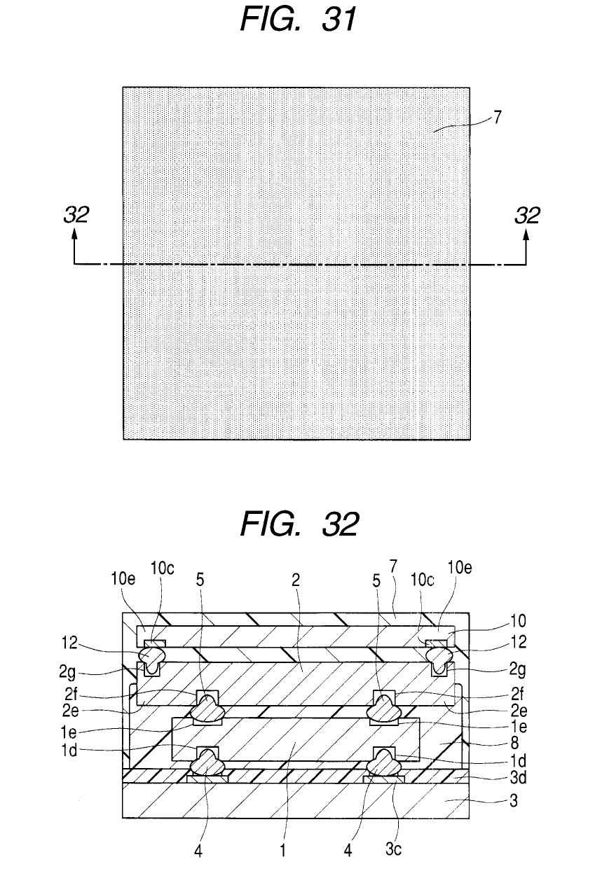

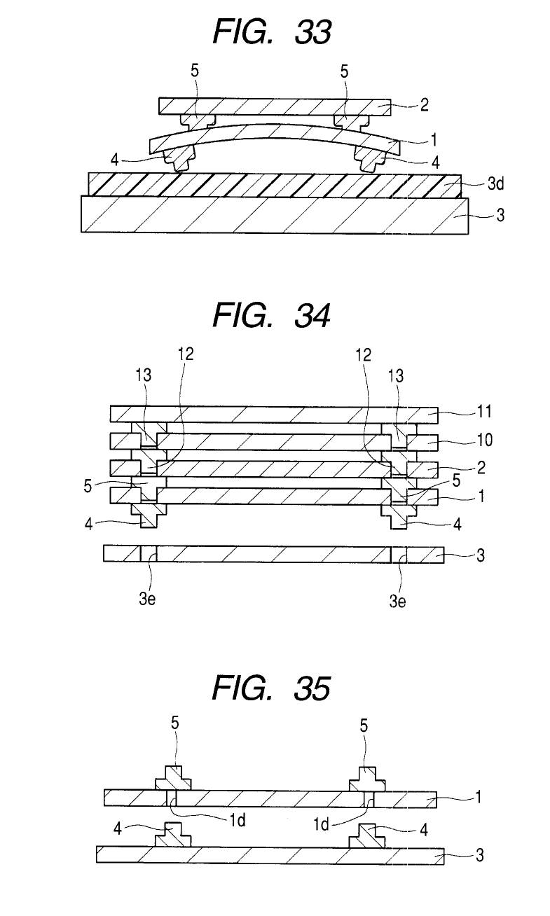

And, FIG. 27 is a plan view showing an example of the structure after under-fill filling in the manufacturing method of the semiconductor device shown in FIG. 1, FIG. 28 is a cross-sectional view showing an example of the structure cut along the A-A line of FIG. 27, FIG. 29 is a plan view showing an example of the structure at the time of third stage chip mounting in the manufacturing method of the semiconductor device shown in FIG. 17, and FIG. 30 is a cross-sectional view showing an example of the structure cut along the A-A line of FIG. 29. Further, FIG. 31 is a plan view showing an example of the structure after the resin seal in the manufacturing method of the semiconductor device shown in FIG. 17, and FIG. 32 is a cross-sectional view showing an example of the structure cut along the A-A line of FIG. 31.

As for the semiconductor device of Embodiment 2, the semiconductor chip of the first stage is mounted like semiconductor package 9 of Embodiment 1 via the gold bump fixed on wiring substrate 3. It is a thing of the 3 stages of chip multi-layer structure by which the semiconductor chip of the second stage was further stacked via the gold bump on this semiconductor chip, and the semiconductor chip of the third stage was further stacked via the gold bump on the semiconductor chip of the second stage. Embodiment 2 takes up and explains SIP14 of 3 stages of chip multi-layer structure as an example of the semiconductor device.

The structure of SIP14 shown in FIG. 17 is explained. Wiring substrate 3 by which a plurality of electrodes 3c were formed in main surface 3a, first semiconductor chip 1 mounted via first gold bump 4 on wiring substrate 3, second semiconductor chip 2 stacked via second gold bump 5 on first semiconductor chip 1, and third semiconductor chip 10 stacked via third gold bump 12 on second semiconductor chip 2 are comprised. It has sealing body 7 which does the resin seal of each semiconductor chip, and a plurality of solder balls 6 formed in back surface 3b of wiring substrate 3. A plurality of solder balls 6 which are external terminals are formed in back surface 3b of wiring substrate 3, and it is SIP14 of the structure same in external appearance as BGA (Ball Grid Array).

First semiconductor chip 1 is mounted on wiring substrate 3. In the case, it is mounted so that main surface 1a may turn to the upper part and back surface 1b may face with main surface 3a of wiring substrate 3 on the other hand. A plurality of pads (surface electrode) 1e are formed in the main surface 1a side, and a plurality of back surface side hole-like electrodes 1d are formed in the back surface 1b side.

On first semiconductor chip 1, second semiconductor chip 2 is stacked via second gold bump 5, the main surface 2a is turned to a lower part (first semiconductor chip 1 side), and it turns back surface 2b up, and is stacked. A plurality of main surface side second hole-like electrodes 2f are formed in the main surface 2a side, and, on the other hand, a plurality of back surface side second hole-like electrodes 2g are formed in the back surface 2b side. The main surface side second hole-like electrode 2f and the back surface side second hole-like electrode 2g corresponding to this are electrically connected.

Hereby as for second gold bump 5 connected to pad 1e of main surface 1a of first semiconductor chip 1, the part is embedded at the main surface side second hole-like electrode 2f of second semiconductor chip 2 of the second stage. Second gold bump 5 and the main surface side second hole-like electrode 2f are electrically connected.

On second semiconductor chip 2, third semiconductor chip 10 is stacked via third gold bump 12, the main surface 10a is turned to a lower part (second semiconductor chip 2 side), and it turns back surface 10b up, and is stacked. As for third gold bump 12 of the third stage connected to pad (surface electrode) 10c of main surface 10a, the part is embedded at the back surface side second hole-like electrode 2g of second semiconductor chip 2 of the second stage in the case. Third gold bump 12 and the back surface side second hole-like electrode 2g are electrically connected.

Here, SIP14 of Embodiment 2 is a thing of the three-dimensional multi-layer structure which connects the wiring between chips and between chip-substrate in three dimensions. That is, flip-chip bonding of the first semiconductor chip 1 of the first stage is made via first gold bump 4 on wiring substrate 3. Furthermore, injection by pressure welding (calking) of the gold bump is done into a main surface side second hole-like electrode 2f, and second semiconductor chip 2 of the second stage is stacked on first semiconductor chip 1. While second semiconductor chip 2 is stacked on first semiconductor chip 1 by this, first semiconductor chip 1 and second semiconductor chip 2 are electrically connected via second gold bump 5 by it. Furthermore, injection by pressure welding (calking) of the gold bump is done into the back surface side second hole-like electrode 2g of second semiconductor chip 2, and third semiconductor chip 10 of the third stage is stacked on second semiconductor chip 2. While third semiconductor chip 10 is stacked on second semiconductor chip 2 by this, second semiconductor chip 2 and third semiconductor chip 10 are electrically connected via third gold bump 12 by it.

In the three-dimensional multi-layer structure of SIP14 of Embodiment 2, the back surface side hole-like electrode 1d is formed in back surface 1b of first semiconductor chip 1 of the first stage. This back surface side hole-like electrode 1d is a hole-like electrode opened at the back surface 1b side at least, and corresponding pad 1e at the side of main surface 1a and a corresponding back surface side hole-like electrode 1d are electrically connected inside the substrate.

Hereby when stacking a chip, first semiconductor chip 1 of the first stage and second semiconductor chip 2 of the second stage are electrically connected by embedding a part of second gold bumps 5 formed in main surface 1a which turned to the upper part at the main surface side second hole-like electrode 2f of second semiconductor chip 2 of the second stage.

Second semiconductor chip 2 of the second stage and third semiconductor chip 10 of the third stage are electrically connected by embedding a part of third gold bumps 12 formed in third semiconductor chip 10 of the third stage at the back surface side second hole-like electrode 2g of second semiconductor chip 2 of the second stage.

Flip chip bonding also of the first semiconductor chip 1 of the first stage is made SIP14 by injecting (calking) the first gold bump 4 beforehand connected on wiring substrate 3 into the back surface side hole-like electrode 1d of first semiconductor chip 1 by pressure welding.

Before first semiconductor chip 1 mounting, in the state which heated wiring substrate 3 at a temperature lower than Tg temperature (softening point) of wiring substrate 3, ultrasonic connection of the first gold bump 4 was made at electrode 3c on main surface 3a of wiring substrate 3. Here, as a temperature which heats wiring substrate 3, it is 120° C., for example. The gold plating layer is formed in electrode 3c of wiring substrate 3.

Connection with first gold bump 4 of first semiconductor chip 1 and connection with second gold bump 5 of second semiconductor chip 2 are made by injecting(calking) each gold bump into the hole-like electrode by pressure welding corresponding to these. Injection by pressure welding into each gold bump's hole-like electrode is performed in the normal temperature process which is not heated intentionally in the case.

Connection with second semiconductor chip 2 of third gold bump 12 on third semiconductor chip 10 is made by injecting (calking) the third gold bump 12 into the back surface side second hole-like electrode 2g of second semiconductor chip 2 by pressure welding. Injection by pressure welding into a back surface side second hole-like electrode 2g of third gold bump 12 is performed under the normal temperature process which is not heated intentionally in the case.

Next, the feature of the structure of SIP14 of Embodiment 2 is explained by making the case of mixed mounting of a microcomputer chip and a memory chip into an example. Since a microcomputer chip exchanges a signal with the outside, it is a best policy to mount in the place nearest to a substrate, i.e., the first stage. On the other hand, since a memory chip operates by control of a microcomputer chip, mounting after the second stage is preferred. Namely when the feature of each chip is taken into consideration, a best policy mounts a microcomputer chip in the first stage, and mounts a memory chip in the second stage.

In the case of the DDR (Double Date Rate) system memory according to large capacity and high speed correspondence etc. as to a memory size of the memory chip is sometimes larger than a microcomputer chip. A DDR system memory is a semiconductor chip which has a memory circuit which performs data transfer synchronizing with both rise and drop of external clock signals, for example. As mentioned above, size of the memory chip may be larger than a microcomputer chip. It becomes the overhang structure where the edge part of the memory chip of the upper stage pushed out from the periphery of the microcomputer chip of a lower stage in the case.

In the case of such an overhang structure, it becomes possible by making an interposer intervene between a microcomputer chip and a memory chip to change the pitch of the surface electrode of a microcomputer chip and a memory chip. By furthermore being filled up with under-fill 8 after interposer mounting, even if it is overhang structure, injection by pressure welding after the third stage (calking processing) can be performed.

That is, in SIP14 shown in FIG. 17, first semiconductor chip 1 of the first stage is used as a microcomputer chip, making second semiconductor chip 2 of the second stage into an interposer, and let third semiconductor chip 10 of the third stage be a memory chip, such as a DDR system memory In this case, rather than first semiconductor chip 1, the side of third semiconductor chip 10 has large size, and constitutes overhang structure. That is, third semiconductor chip 10 has pushing out part 10e which pushed out from first semiconductor chip 1.

By forming the interposer of the second stage in the same size as third semiconductor chip 10, second semiconductor chip 2 (interposer) will also have pushing out part 2e which pushed out from first semiconductor chip 1, and constitutes overhang structure. However, by being filled up with under-fill 8 after interposer mounting, even if it is overhang structure, it becomes possible to perform injection by pressure welding (calking processing) of the third stage. That is, the pushing out part 2e is supported from a lower part by filling up pushing out part 2e lower part of second semiconductor chip 2 (interposer) with under-fill 8. Therefore, it becomes possible to inject the third gold bump 12 of third semiconductor chip 10 (memory chip) into the back surface side second hole-like electrode 2g formed in pushing out part 2e by pressure welding.

It becomes possible to change the pitch of the surface electrode of a microcomputer chip and a memory chip by making an interposer (second semiconductor chip 2) intervene between the microcomputer chip (first semiconductor chip 1) and memory chip (third semiconductor chip 10) from which a size differs.

Since it is the same as that of semiconductor package 9 of Embodiment 1 about the other structures of SIP14 of Embodiment 2, the duplicate explanation is omitted.

Next, the manufacturing method of SIP14 of Embodiment 2 is explained using the manufacture process-flow chart shown in FIG. 18.

First, the wiring substrate preparation shown in Step S1 of FIG. 18 is made. Here, as shown in FIG. 19 and FIG. 20, wiring substrate 3 which has main surface 3a and back surface 3b which faces main surface 3a and by which a plurality of electrodes 3c were formed in main surface 3a is prepared. The gold plating layer is formed on a plurality of electrodes 3c.

Then, as shown in FIG. 17, first semiconductor chip 1 which has main surface 1a, and back surface 1b opposite to main surface 1a, and has a back surface side hole-like electrode 1d opened at the back surface 1b side, and second gold bump 5 arranged on pad 1e of main surface 1a, and to which the back surface side hole-like electrode 1d and pad 1e were electrically further connected by internal wiring is prepared. Second gold bump 5 is a stud bump, and is a bump connected using wire bonding on pad 1e of main surface 1a of first semiconductor chip 1. In the case, second gold bump 5 is formed so that second gold bump's 5 diameter may become larger than the hole size of the main surface side second hole-like electrode 2f of second semiconductor chip 2. That is, second gold bump's 5 diameter is formed in the degree in which injection by pressure welding into a main surface side second hole-like electrode 2f is possible for second gold bump 5 more greatly than the hole size of the main surface side second hole-like electrode 2f of second semiconductor chip 2.

Second semiconductor chip 2 which has main surface 2a, and back surface 2b opposite to main surface 2a, in which the main surface side second hole-like electrode 2f opened at the main surface 2a side and the back surface side second hole-like electrode 2g opened at the back surface 2b side are formed, and to which the main surface side second hole-like electrode 2f and the back surface side second hole-like electrode 2g were furthermore connected by internal wiring is prepared.

Third semiconductor chip 10 which has main surface 10a, and back surface 10b opposite to main surface 10a and with which third gold bump 12 has been arranged on pad 10c of main surface 10a is prepared. Third gold bump 12 is also a stud bump, and is the bump connected using wire bonding on pad 10c of main surface 10a of third semiconductor chip 10. In the case, third gold bump 12 is formed so that third gold bump's 12 diameter may become larger than the hole size of the back surface side second hole-like electrode 2g of second semiconductor chip 2. That is, third gold bump's 12 diameter is formed in the degree in which injection by pressure welding into a back surface side second hole-like electrode 2g is possible for third gold bump 12 more greatly than the hole size of the back surface side second hole-like electrode 2g of second semiconductor chip 2.

First semiconductor chip 1 is a microcomputer chip, second semiconductor chip 2 is an interposer, and third semiconductor chip 10 is a memory chip, such as a DDR system memory Therefore, third semiconductor chip 10 has size larger than first semiconductor chip 1, and third semiconductor chip 10 has pushing out part 10e where the circumference pushed out from first semiconductor chip 1. Second semiconductor chip 2 is also formed in the same size as third semiconductor chip 10, therefore it has pushing out part 2e.

Then, as shown in Step S2, FIG. 21, and FIG. 22, first gold bump 4 is connected on a plurality of electrodes 3c of main surface 3a of wiring substrate 3. Here, in the state which heated wiring substrate 3 at a temperature lower than Tg temperature (softening point) of wiring substrate 3, first gold bump 4 is arranged by ultrasonic connection at electrode 3c on main surface 3a of wiring substrate 3. As a temperature which heats wiring substrate 3, it is 120° C., for example. The gold plating layer is formed in electrode 3c of wiring substrate 3.

First gold bump 4 as well as second gold bump 5 is a stud bump formed using wire bonding. In the case, first gold bump 4 is formed so that first gold bump's 4 diameter may become larger than the hole size of the back surface side hole-like electrode 1d of first semiconductor chip 1. That is, first gold bump's 4 diameter is formed in the degree in which injection by pressure welding into a back surface side hole-like electrode 1d is possible for first gold bump 4 more greatly than the hole size of the back surface side hole-like electrode 1d of first semiconductor chip 1.

Then, the first stage chip mounting which is shown in Step S3 of FIG. 18 is performed. Here, as shown in FIG. 23 and FIG. 24, the back surface 1b, and main surface 3a of wiring substrate 3 are made to face, and first semiconductor chip 1 to which second gold bump 5 was connected on pad 1e of main surface 1a is arranged. That is, back surface 1b of first semiconductor chip 1 is disposed to face on main surface 3a of wiring substrate 3 in main surface 3a of wiring substrate 3.

Then, injection by pressure welding of the first gold bump 4 on wiring substrate 3 corresponding to this is done in the atmosphere of normal temperature into the back surface side hole-like electrode 1d of first semiconductor chip 1, and first semiconductor chip 1 is mounted. Here, as shown in FIG. 24, in the atmosphere of normal temperature, injection by pressure welding (calking processing) is done into the back surface side hole-like electrode 1d of first semiconductor chip 1, and first gold bump 4 on wiring substrate 3 is embedded at it.

In the case, first gold bump 4 is formed so that the diameter may become large slightly from the hole size of back surface side hole-like electrode 1d. For this reason, injection by pressure welding (calking processing) of the first gold bump 4 can be done into back surface side hole-like electrode 1d, and flip-chip bonding of the first semiconductor chip 1 can be made by this.

The normal temperature is a temperature lower enough than the temperature (120˜150° C.) at the time of doing bonding of the first gold bump 4 to wiring substrate 3, for example. When it has another way of speaking, temperature is a temperature as it is which is not applied intentionally That is, while it receives heating by 120˜150° C., for example when connecting first gold bump 4 to wiring substrate 3, especially when flip-chip bonding the first semiconductor chip 1 by pressure welding injection, it is carried out under the normal temperature, without heating.

Therefore, in the manufacturing method of the semiconductor device of Embodiment 1, at the time of flip-chip bonding of first semiconductor chip 1 which is a chip of the first stage, it can be connected without using a heating process.

Then, interposer (second stage chip) mounting which is shown in Step S4 of FIG. 18 is performed. First, as shown in FIG. 25 and FIG. 26, main surface 2a of second semiconductor chip 2 is disposed to face on main surface 1a of first semiconductor chip 1. That is, main surface 2a of second semiconductor chip 2 is disposed to face on main surface 1a of first semiconductor chip 1 in main surface 1a of first semiconductor chip 1.

Then, injection by pressure welding of the second gold bump 5 connected to first semiconductor chip 1 is done into the main surface side second hole-like electrode 2f of second semiconductor chip 2 in the atmosphere of normal temperature, and second semiconductor chip 2 is stacked on first semiconductor chip 1. Here, as shown in FIG. 26, in the atmosphere of normal temperature, injection by pressure welding (calking processing) is done into the main surface side second hole-like electrode 2f of second semiconductor chip 2, and second gold bump 5 on first semiconductor chip 1 is embedded at it.

In the case, second gold bump 5 is formed so that the diameter may become large slightly from the hole size of a main surface side second hole-like electrode 2f. For this reason, injection by pressure welding (calking processing) of the second gold bump 5 can be done into a main surface side second hole-like electrode 2f, and flip-chip bonding of the second semiconductor chip 2 can be made on first semiconductor chip 1 by this.

Also in the mounting step of the semiconductor chip (interposer) of the second stage, the normal temperature is a temperature lower enough than the temperature (120˜150° C.) at the time of doing bonding of the first gold bump 4 to wiring substrate 3, for example. When it has another way of speaking, temperature is a temperature as it is which is not applied intentionally That is, while it receives heating by 120˜150° C., for example when connecting first gold bump 4 to wiring substrate 3, also when flip-chip bonding the second semiconductor chip 2 on first semiconductor chip 1 by pressure welding injection, it is carried out under normal temperature, without heating especially.

Therefore, also in second semiconductor chip 2 which is a semiconductor chip of the second stage mounting, flip-chip bonding can be made on first semiconductor chip 1 without using a heating process.

Then, under-fill filling shown in Step S5 of FIG. 18 is performed. Here, as shown in FIG. 27 and FIG. 28, between first semiconductor chip 1 and wiring substrates 3, between second semiconductor chip 2 (interposer) and wiring substrate 3, between first semiconductor chip 1 and second semiconductor chips 2 and the circumference of second semiconductor chip 2 are filled up with under-fill 8 (resin). Baking processing of under-fill 8 is performed after filling.

Although the bake temperature of under-fill 8 is about 150° C., it can also usually lower bake temperature from 150° C. by lowering the cure rate of resin. Therefore, it is possible to fill up under-fill 8 with lowering bake temperature to the degree at which a chip warp does not generate, even if it is a stage in the middle of a chip-stack.

Hereby pushing out part 2e lower part of second semiconductor chip 2 (interposer) is also filled up with under-fill 8, and it will be in the state where pushing out part 2e was supported with resin.

About filling of under-fill 8, after mounting first semiconductor chip 1 of the first stage (after the termination of step S3 of FIG. 18), it may be filled up with under-fill 8 to first semiconductor chip 1.

Then, third stage chip mounting which is shown in Step S6 of FIG. 18 is performed. As shown in FIG. 29 and FIG. 30, main surface 10a of third semiconductor chip 10 is disposed to face on back surface 2b of second semiconductor chip 2. That is, on back surface 2b of second semiconductor chip 2, to back surface 2b of second semiconductor chip 2, main surface 10a of third semiconductor chip 10 is disposed to face.

Then, injection by pressure welding of the third gold bump 12 connected to third semiconductor chip 10 is done in the atmosphere of normal temperature into the back surface side second hole-like electrode 2g of second semiconductor chip 2, and third semiconductor chip 10 (memory chip) is stacked on second semiconductor chip 2. Here, as shown in FIG. 30, in the atmosphere of normal temperature, injection by pressure welding (calking processing) is done into the back surface side second hole-like electrode 2g of second semiconductor chip 2, and third gold bump 12 on third semiconductor chip 10 is embedded at it.

Second semiconductor chip 2 (interposer) and third semiconductor chip 10 (memory chip) have pushing out parts 2e and 10e which pushed out from first semiconductor chip 1 (microcomputer chip), respectively in the case. Therefore, injection by pressure welding of the third gold bump 12 of third semiconductor chip 10 is done into the back surface side second hole-like electrode 2g formed in pushing out part 2e of second semiconductor chip 2. Since it is in the state where pushing out part 2e lower part of second semiconductor chip 2 was already filled up with under-fill 8, and pushing out part 2e was supported with resin at the time of the injection by pressure welding, the injection by pressure welding can be ensured.

Here, since third gold bump 12 is formed so that the diameter may become larger than the hole size of a back surface side second hole-like electrode 2g, injection by pressure welding (calking processing) of the third gold bump 12 can be done into a back surface side second hole-like electrode 2g. Third semiconductor chip 10 can be stacked on second semiconductor chip 2 by this.

Also in the mounting step of the semiconductor chip (memory chip) of the third stage, the normal temperature is a temperature lower enough than the temperature (120˜150° C.) at the time of doing bonding of the first gold bump 4 to wiring substrate 3, for example. When it has another way of speaking, temperature is a temperature as it is which is not applied intentionally. That is, while it receives heating by 120˜150° C., for example, when connecting first gold bump 4 to wiring substrate 3, also when stacking third semiconductor chip 10 on second semiconductor chip 2 by pressure welding injection, it is carried out under normal temperature, without heating especially.

Therefore, also in third semiconductor chip 10 which is a semiconductor chip of the third stage mounting, it can be stacked on second semiconductor chip 2 without using a heating process.

Then, the resin seal shown in Step S7 of FIG. 18 is performed. Here, as shown in FIG. 31 and FIG. 32, on wiring substrate 3, the resin seal of first semiconductor chip 1, second semiconductor chip 2, third semiconductor chip 10, and each gold bump is done, and sealing body 7 which comprises resin for sealing is formed.

It may be filled up with under-fill 8 as a substitute of a resin seal.

Then, ball attachment shown in Step S8 is performed. Here, as shown in FIG. 17, solder ball 6 which are a plurality of external terminals is joined to back surface 3b of wiring substrate 3. Individual separation shown in Step S9 is performed, and it becomes assembly completion of SIP(semiconductor device) 14.

According to the manufacturing method of the semiconductor device of Embodiment 2, ultrasonic connection of the first gold bump 4 is made, heating wiring substrate 3 on a plurality of electrodes 3c of wiring substrate 3. Then, each chip-stack of first semiconductor chip 1, second semiconductor chip 2, and third semiconductor chip 10 can be performed in a normal temperature process.

Hereby second semiconductor chip 2 and third semiconductor chip 10 after the second stage can be stacked in the state where there is no warp in first semiconductor chip 1 of the first stage. As a result, injection by pressure welding of each gold bump of the semiconductor chip at the side of an upper stage to stack can be done surely enough into the hole-like electrode of the semiconductor chip at the side of a lower stage. The quality and reliability of SIP(semiconductor device) 14 can be improved.

Since a different semiconductor chip from the coefficient of thermal expansion of wiring substrate 3 is not arranged on main surface 3a of wiring substrate 3 even if wiring substrate 3 expands under the influence of heat which heats wiring substrate 3, when first gold bump 4 is fixed to electrode 3c of wiring substrate 3, a warp does not happen in wiring substrate 3.

Even if it is the overhang structure where a memory chip (third semiconductor chip 10) has pushing out part 10e in bigger size than a microcomputer chip (first semiconductor chip 1), by making an interposer intervene between a microcomputer chip and a memory chip, and making pushing out part 2e lower part of an interposer fill up with under-fill 8, pushing out part 2e of an interposer can be supported with resin.

Hereby even if it is the structure that the memory chip of the third stage overhangs, the memory chip of the third stage can be stacked by pressure welding injection.

It becomes possible by making an interposer intervene between a microcomputer chip and a memory chip to change the pitch of the surface electrode of a microcomputer chip and a memory chip.

Since it is the same as that of Embodiment 1 about the other effects acquired by the manufacturing method of the semiconductor device of Embodiment 2, the duplicate explanation is omitted.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

For example, the each hole-like electrode of Embodiment 1 and 2 may be a penetration electrode, or may be a hole-like electrode opened only at at least one surface without penetrating.

How many stages may the number of laminations of the semiconductor chip in semiconductor package 9 or SIP14 be, and may be stacked how many sheets according to need also about the number of mounting of an interposer.

The present invention is suitable for the assembly of the electronic device which stacks a plurality of semiconductor chips.

What is claimed is:

1. A manufacturing method of a semiconductor device, comprising the steps of:
(a) providing a wiring substrate having a main surface, a back surface opposite to the main surface, and a plurality of electrodes formed in the main surface;
(b) providing a first semiconductor chip having a main surface, a back surface opposite to the main surface, a main surface side first hole-like electrode opened at the main surface and a back surface side first hole-like electrode opened at the back surface, the main surface side first hole-like electrode and the back surface side first hole-like electrode being electrically connected to each other;
(c) providing a second semiconductor chip having a main surface and a back surface opposite to the main surface, and a second gold bump arranged over a surface electrode of the main surface;
(d) connecting a first gold bump over a plurality of electrodes of the wiring substrate while heating the wiring substrate;
(e) after the step (d), injecting the first gold bump of the wiring substrate into the main surface side first hole-like electrode of the first semiconductor chip by pressuring welding and flip-chip bonding the first semiconductor chip under normal temperature, after disposing the first semiconductor chip over the wiring substrate such that a main surface of the wiring substrate and a main surface of the first semiconductor chip are facing to each other; and
(f) injecting the second gold bump of the second semiconductor chip into the back surface side first hole-like electrode of the first semiconductor chip by pressure welding and stacking the second semiconductor chip over the first semiconductor chip under normal temperature, after the second semiconductor chip over the back surface of the first semiconductor chip such that the main surface of the second semiconductor chip and the back surface of the first semiconductor chip are facing to each other.

2. A manufacturing method of a semiconductor device according to claim 1, wherein
a main surface side first hole-like electrode and a back surface side first hole-like electrode of the first semiconductor chip are formed constituting a pair, and both are formed in a position which shifted to a plane direction.

3. A manufacturing method of a semiconductor device according to claim 1, wherein
the first semiconductor chip is an interposer.

4. A manufacturing method of a semiconductor device according to claim 1, wherein
a step which does a resin seal of two or more stages of semiconductor chips, and a gold bump after stacking the two or more stages of semiconductor chips over the wiring substrate is included.

5. A manufacturing method of a semiconductor device according to claim 1, wherein
temperature in the step (e) and the step (f) is lower than temperature in the step (d).

6. A manufacturing method of a semiconductor device according to claim 1, wherein
the step (e) and the step (f) are performed in a state where temperature is not applied.

7. A manufacturing method of a semiconductor device according to claim 1, wherein
the first gold bump's diameter is larger than a hole size of the main surface side first hole-like electrode, and the second gold bump's diameter is larger than a hole size of the back surface side first hole-like electrode.

8. A manufacturing method of a semiconductor device according to claim 1, wherein
the first and the second gold bump are stud bumps.

9. A manufacturing method of a semiconductor device, comprising the steps of:
(a) providing a wiring substrate having a main surface, a back surface opposite to the main surface, and a plurality of electrodes formed in the main surface;
(b) providing a first semiconductor chip having a main surface, a back surface opposite to the main surface, and a main surface side first hole-like electrode opened at the main surface and a back surface side first hole-like electrode opened at the back surface, the main surface side first hole-like electrode and the back surface side first hole-like electrode being electrically connected;
(c) providing a second semiconductor chip having a main surface, a back surface opposite to the main surface, and a second gold bump arranged over a surface electrode of the main surface;
(d) injecting the second gold bump of the second semiconductor chip into the back surface side first hole-like electrode of the first semiconductor chip by pressure welding, and stacking the second semiconductor chip over the first semiconductor chip under normal temperature after disposing the second semiconductor chip over the first semiconductor chip so that the main surface of the second semiconductor chip and the back surface of the first semiconductor chip are facing to each other;
(e) connecting a first gold bump over a plurality of electrodes of the wiring substrate while heating the wiring substrate; and
(f) after the step (e), injecting the first gold bump over the wiring substrate into the main surface side first hole-like electrode of the first semiconductor chip by pressure welding, and stacking the first and the second semiconductor chip in the wiring substrate upper part under normal temperature after disposing the wiring substrate and the first semiconductor chip so that the main surface of the wiring substrate, and the main surface of the first semiconductor chip are facing to each other.

10. A manufacturing method of a semiconductor device, comprising the steps of:
(a) providing a wiring substrate having a main surface, a back surface opposite to the main surface, and a plurality of electrodes formed in the main surface;
(b) providing a first semiconductor chip having a main surface, a back surface opposite to the main surface, a back surface side first hole-like electrode opened at the back surface, and a second gold bump arranged over a surface electrode of the main surface, the back surface side first hole-like electrode and the second gold bump being electrically connected to each other;
(c) providing a second semiconductor chip having a main surface, a back surface opposite to the main surface, a main surface side second hole-like electrode opened at the main surface and a back surface side second hole-like electrode opened at the back surface, the main surface side second hole-like electrode and the back surface side second hole-like electrode being electrically connected to each other;
(d) providing a third semiconductor chip having a main surface, a back surface opposite to the main surface, a third hole-like electrode opened at the back surface and a third gold bump arranged over a surface electrode of the main surface, the third hole-like electrode and the third gold bump being electrically connected to each other;
(e) connecting a first gold bump over a plurality of electrodes of the wiring substrate while heating the wiring substrate;
(f) after the step (e), flip-chip bonding the first semiconductor chip over the wiring substrate by injecting the first gold bump over the wiring substrate into the back surface side first hole-like electrode of the first semiconductor chip by pressure welding under normal temperature;
(g) stacking the second semiconductor chip over the first semiconductor chip by injecting the second gold bump over the main surface of the first semiconductor chip into the main surface side second hole-like electrode of the second semiconductor chip by pressure welding under normal temperature after disposing the second semiconductor chip over the first semiconductor chip so that the main surface of the second semiconductor chip and the main surface of the first semiconductor chip are facing to each other; and
(h) stacking the third semiconductor chip over the second semiconductor chip by injecting the third gold bump of the third semiconductor chip into the back surface side second hole-like electrode of the second semiconductor chip by pressure welding under normal temperature after disposing the third semiconductor chip over the second semiconductor chip so that the main surface of the third semiconductor chip and the back surface of the second semiconductor chip are facing to each other;
wherein the first semiconductor chip is a microcomputer chip, the second semiconductor chip is an interposer, and the third semiconductor chip is a memory chip.

11. A manufacturing method of a semiconductor device according to claim 10, wherein
the memory chip has a memory circuit performing data transfer synchronizing with both of a rise and a drop of external clock signals.

12. A manufacturing method of a semiconductor device according to claim 10, wherein
under-fill is filled up between the wiring substrate and the interposer after the step (g), and after filling up with the under-fill, the step (h) is performed.

13. A manufacturing method of a semiconductor device according to claim 10, wherein
the interposer and the memory chip have a pushing out part which pushed out from the microcomputer chip, and pressure welding injection of a third gold bump of the third semiconductor chip is done at the back surface side second hole-like electrode formed in a pushing out part of the interposer.
